(19) United States
(12) Patent Application Publication
(10) Pub. No.: US 2024/0282740 A1
(43) Pub. Date: Aug. 22, 2024

(54) INTEGRATED CIRCUIT (IC) PACKAGE INCLUDING A CAPACITOR FORMED IN A CONDUCTIVE ROUTING REGION

(71) Applicant: Microchip Technology Incorporated, Chandler, AZ (US)

(72) Inventors: Matthew Martin, Gilbert, AZ (US); Bomy Chen, Newark, CA (US); Julius Kovats, Manitou Springs, CO (US)

(73) Assignee: Microchip Technology Incorporated, Chandler, AZ (US)

(21) Appl. No.: 18/215,351

(22) Filed: Jun. 28, 2023

Related U.S. Application Data
(60) Provisional application No. 63/447,115, filed on Feb. 21, 2023.

(51) Int. Cl. H01L 23/00; H01L 23/31; H01L 25/065

(52) U.S. Cl. CPC H01L 24/24; H01L 23/3121; H01L 24/19; H01L 24/20; H01L 24/82; H01L 25/0655; H01L 2224/19; H01L 2224/2101; H01L 2224/211; H01L 2224/215; H01L 2224/24011; H01L 2224/24101; H01L 2224/24137; H01L 2224/82106; H01L 2924/01029; H01L 2924/1205

(57) ABSTRACT

An integrated circuit (IC) package includes a bare die mounted on a substrate, and a conductive routing region formed over the bare die, the conductive routing region including a conductive routing structure and a capacitor formed in multiple conductive routing layers. The bare die includes IC circuitry, a dielectric region at least partially encapsulating the IC circuitry, and an IC contact exposed through the dielectric region. The conductive routing structure formed in the conductive routing region is conductively connected to the IC contact of the bare die. The capacitor formed in the conductive routing region includes a first capacitor electrode and a second capacitor electrode formed in one or more of the conductive routing layers, and a capacitor dielectric element formed between the first capacitor electrode and the second capacitor electrode.

### RELATED PATENT APPLICATION

This application claims priority to commonly owned U.S. Provisional Patent Application No. 63/447,115 filed Feb. 21, 2023, the entire contents of which are hereby incorporated by reference for all purposes.

### TECHNICAL FIELD

The present disclosure relates to integrated circuit (IC) packages, and more particularly to an IC package including a capacitor formed in a conductive routing region, and methods of forming such an IC package.

### BACKGROUND

Certain types of IC packages, for example certain system-in-packages (SiP) and panel level packages (PLP) include multiple chips enclosed or otherwise provided in a single package. As used herein, a chip is also referred to as a “bare die,” wherein a bare die (or chip) includes IC circuitry (e.g., transistor, resistor, capacitor, diode, inductor, logic gate, operational amplifier, and/or other IC circuit element(s), a dielectric (e.g., passivation region) at least partially encapsulating the IC circuitry, and at least one contact (e.g., at least one top metal element, bond pad, or other contact) exposed through the dielectric to allow electrical connection to the IC circuitry. Some example types of bare dies include microcontrollers (MCU), central processing units (CPUs), application-specific integrated circuits (ASICs), field programmable gate arrays (FPGAs), drivers, memory chips, and system-on-a-chip (SoC) devices.

A typical SiP or PLP includes multiple bare dies mounted on a substrate, and a redistribution layer (RDL) region including conductive metal structures connecting selected bare dies to each other and/or to external devices. Some SiPs and PLPs include a discrete capacitor mounted on the package substrate along with bare dies, the discrete capacitor electrically connected between two or more bare dies by a conductive RDL structure formed in the RDL region, to provide galvanic isolation between the two or more bare dies. For example, an SiP or PLP may include a discrete capacitor mounted on the package substrate alongside a high-voltage bare die (e.g., a high-voltage driver or a high-voltage power device) and a low-voltage bare die (e.g., a low-voltage microcontroller or low-voltage FPGA), wherein the capacitor is connected between the high-voltage bare die and low-voltage bare die by a conductive RDL structure formed in the RDL region, to provide galvanic isolation between the bare dies. Such discrete capacitors may be expensive and may require a relatively large area (footprint).

There is a need for improved integration of capacitors in IC packages, e.g., SiPs and PLPs, for example with low cost and/or compact size as compared with conventional solutions.

### SUMMARY

Examples of the present disclosure provide IC packages, for example panel-level packages (PLPs), system-in-packages (SiPs) or other chip-first packages including one or more bare dies (also referred to as chips) mounted on a substrate, and a conductive routing region (e.g., an RDL region) formed over the bare die(s)), wherein the conductive routing region includes both (a) a conductive routing structure (e.g., to connected respective bare dies to each other and/or to external contacts) and (b) a capacitor, which may be referred to herein as an “in-package capacitor.”

Some examples provide “mixed-voltage” packages (e.g., PLPs or SiPs) including multiples bare dies that operate at different voltages (e.g., including at least one high-voltage die and at least one low-voltage die), wherein such bare dies may be galvanically isolated by an in-package capacitor formed in the conductive routing region (e.g., RDL region) formed over the dies.

In some examples, the in-package capacitor may have a vertically oriented structure, e.g., a metal-insulator-metal (MIM) capacitor including a pair of capacitor electrodes formed in respective routing layers in the conductive routing region (e.g., respective RDL metal layers), and a capacitor dielectric formed between the pair of capacitors electrodes. In some examples, the capacitor dielectric comprises a high-k dielectric material, e.g., having a dielectric constant above 4.

In other examples, the in-package capacitor may have a laterally oriented structure, e.g., a metal-oxide-metal (MOM) capacitor including a pair of capacitor electrodes having interdigitated fingers formed in at least one common (same) routing layer in the conductive routing region (e.g., at least one common RDL metal layer).

In one aspect, an IC package includes a bare die mounted on a substrate, and a conductive routing region formed over the bare die, the conductive routing region including a conductive routing structure and a capacitor formed in multiple conductive routing layers. The bare die includes IC circuitry, a dielectric region at least partially encapsulating the IC circuitry, and an IC contact exposed through the dielectric region. The conductive routing structure formed in the conductive routing region is conductively connected to the IC contact of the bare die. The capacitor formed in the conductive routing region includes a first capacitor electrode and a second capacitor electrode formed in one or more of the conductive routing layers, and a capacitor dielectric element formed between the first capacitor electrode and the second capacitor electrode.

In some examples, the IC package comprises a chip-first package.

In some examples, the conductive routing region comprises a redistribution layer (RDL) region, wherein respective conductive routing layers of the multiple conductive routing layers comprise respective RDL layers.

In some examples, the conductive routing structure includes at least one conductive element separate from the capacitor and formed in a common conductive routing layer as the first capacitor electrode or the second capacitor electrode.

In some examples, the first capacitor electrode and the second capacitor electrode are formed in different conductive routing layers of the multiple conductive routing layers.

In some examples, the first capacitor electrode and the second capacitor electrode are at least partially formed in a common conductive routing layer of the multiple conductive routing layers.

In some examples, the capacitor comprises a Metal-Insulator-Metal (MIM) capacitor.

For example, the first capacitor electrode may comprise a first plate electrode, and the second capacitor electrode may comprise a second plate electrode. In some examples, the capacitor dielectric element is formed in a via layer between the first plate electrode and second plate electrode.

In some examples, the capacitor comprises a Metal-Oxide-Metal (MOM) capacitor. For example, the first capacitor electrode may comprise a first comb-shaped structure formed in a first conductive routing layer of the multiple conductive routing layers, the first comb-shaped structure including first elongated fingers, and the second capacitor electrode may comprise a second comb-shaped structure formed in the first conductive routing layer, the second comb-shaped structure including second elongated fingers interdigitated with the first elongated fingers of the first comb-shaped structure.

In some examples, the multiple conductive routing layers include multiple metal layers alternating with multiple via layers, the first capacitor electrode is formed at least in part in a first respective metal layer of the multiple metal layers, the second capacitor electrode is formed at least in part in a second respective metal layer of the multiple metal layers, and the capacitor dielectric element is formed in a respective via layer of the multiple via layers.

In some examples, the IC package includes a further bare die mounted to the substrate, and the capacitor is electrically coupled between the bare die and the further bare die.

In some examples, the conductive routing structure includes an external contact element contactable by an external device, and the capacitor is electrically coupled between the bare die and the external contact element.

One aspect provides a method of forming an IC package. A bare die is mounted on a substrate, wherein the bare die includes IC circuitry, a dielectric region at least partially encapsulating the IC circuitry, and an IC contact exposed through the dielectric region. After mounting the bare die on the substrate, a conductive routing region including multiple conductive routing layers is formed over the bare die. Forming the conductive routing region includes (a) forming a conductive routing structure including conductive elements formed in respective conductive routing layers of the multiple conductive routing layers, wherein the conductive routing structure is conductively connected to the IC contact of the bare die, and (b) forming a capacitor, including forming a first capacitor electrode and a second capacitor electrode in one or more conductive routing layers of the multiple conductive routing layers, and forming a capacitor dielectric element between the first capacitor electrode and the second capacitor electrode.

In some examples, forming the conductive routing region including multiple conductive routing layers comprises forming a redistribution layer (RDL) region including multiple RDL layers.

In some examples, the method includes forming at least one conductive element of the conductive routing structure, separate from the capacitor, in a common conductive routing layer as the first capacitor electrode or the second capacitor electrode.

In some examples, the multiple conductive routing layers include multiple metal layers alternating with multiple via layers, the first capacitor conductive element is formed in a first respective metal layer of the multiple metal layers, the second capacitor conductive element is formed in a second respective metal layer of the multiple metal layers, and the capacitor dielectric element is formed in a respective via layer of the multiple via layers between the first respective metal layer of the multiple metal layers and the second respective metal layer of the multiple metal layers.

In some examples, forming the capacitor dielectric element comprises depositing a dielectric material over the first capacitor electrode.

In some examples, forming the capacitor dielectric element comprises depositing a dielectric material using an additive manufacturing process.

In some examples, forming the capacitor dielectric element includes using a laser-based removal process to form at least one opening adjacent the first capacitor electrode, and filling the at least one opening with a dielectric material.

One aspect provides an IC package including a substrate, a first bare die and a second bare die mounted on the substrate, and a conductive routing layer stack formed over the first bare die and the second bare die. The conductive routing layer stack includes (a) at least one conductive routing structure conductively connected to at least one of the first bare die and the second bare die, and (b) a capacitor including a first capacitor electrode conductively connected to the first bare die, a second capacitor electrode conductively connected to the second bare die, and a capacitor dielectric element formed between the first capacitor electrode and the second capacitor electrode.

In some examples, the conductive routing layer stack comprises multiple RDL layers.

In some examples, the capacitor comprises a MIM capacitor. In other examples, the capacitor comprises a MOM capacitor.

### BRIEF DESCRIPTION OF THE DRAWINGS

Example aspects of the present disclosure are described below in conjunction with the figures, in which:

FIG. 1 is a cross-sectional side view of an example IC package, e.g., a panel-level package (PLP), including a capacitor formed in a conductive routing region over at least one bare die, according to one example;

FIG. 2 is a cross-sectional side view of an example IC package including the capacitor shown in FIG. 1, wherein the capacitor is capacitively connected between two bare dies mounted to the IC package;

FIG. 3 is a cross-sectional side view of an example IC package including the capacitor shown in FIG. 1, wherein the capacitor is capacitively connected between a bare die and an external contact element;

FIGS. 4A and 4B illustrate an example IC package (e.g., a PLP) including an example Metal-Oxide-Metal (MOM) capacitor formed in a conductive routing region over at least one bare die;

FIGS. 5A-5E illustrate an example method of forming the example IC package shown in FIG. 2;

FIGS. 6A-6K illustrate an example method of forming the example IC package shown in FIGS. 4A-4B; and

FIG. 7 shows an example panel including an array of PLPs formed thereon, wherein respective PLPs include at least one in-package capacitor according to the present disclosure.

It should be understood the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

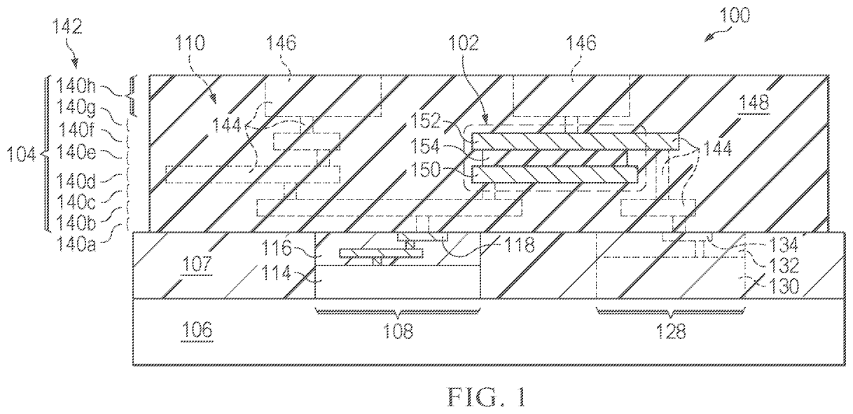

FIG. 1 is a cross-sectional side view of an example integrated circuit (IC) package 100 including an in-package capacitor 102 formed in a conductive routing region 104, according to one example. The example IC package 100 may include a substrate 106, a bare die 108 mounted on the substrate 106, the conductive routing region 104 (e.g., an RDL region) formed over the bare die 108, and a conductive routing structure 110, the conductive routing structure 110 and the in-package capacitor 102 are formed in the conductive routing region 104. In some examples, the IC package 100 may comprise a panel-level package (PLP) or a system-in-package (SiP) formed by a chip-first method wherein the bare die 108 is mounted to the substrate 106 prior to forming the conductive routing region 104 over the bare die 108. Accordingly, the IC package 100 may be referred to as a chip-first package.

The bare die 108 may comprise any type of bare die or chip, for example a microcontroller (MCU), central processing unit (CPU), application-specific integrated circuit (ASIC), field programmable gate array (FPGA), digital signal processor (DSP), driver, memory, analog to digital converter (ADC), digital to analog converter (DAC), silicon carbide (SiC) chip, or system-on-a-chip (SoC), without limitation. The bare die 108 may include IC circuitry 114, a dielectric region 116 at least partially encapsulating the IC circuitry 114, and an IC contact 118 exposed through the dielectric region 116. The IC circuitry 114 may include at least one transistor, resistor, capacitor, diode, inductor, logic gate, operational amplifier, and/or other IC circuit element(s). The dielectric region 116 may comprise a polyimide or other passivation region or material, or any other insulative material at least partially covering the IC circuitry 114, for example to provide electrical insulation, physical protection and/or structural support. The IC contact 118 may comprise a top metal element, bond pad, or other conductive element allowing electrical connection between the IC circuitry 114 and external electronics (i.e., outside the bare die 108). For example, the IC contact 118 may be exposed through the dielectric region 116.

As discussed below, in some examples the IC package 100 may include multiple bare dies mounted on the substrate 106. For example, FIG. 1 shows the bare die 108 and an optional further bare die 128, which may include respective IC circuitry 130, a dielectric region 132 at least partially encapsulating the IC circuitry 130, and an IC contact 134 exposed through the dielectric region 132. In some examples, the IC package 100 may be formed as a panel-level package (PLP) or a system-in-package (SiP) including any number of bare dies (e.g., at least bare dies 108 and 128), wherein PLP or SiP is formed by a chip-first method in which the bare dies (e.g., at least bare dies 108 and 128) are mounted to the substrate 106 prior to forming the conductive routing region 104 (e.g., RDL region) over the bare dies. The bare die 108 and further bare die 128 may also be referred to as a first bare die 108 and a second bare die 128.

The substrate 106 may comprise a polymer, e.g., an epoxy, polyimide, or polybenzoxazole (PBO)), or other suitable substrate for mounting bare die(s). The bare die 108 and (optional) further bare die 128 mounted on the substrate 106 may be partially encapsulated by a mold compound 107 (e.g., an epoxy), or a similar material as the underlying substrate 106.

The conductive routing region 104 formed over the bare die 108 (and optional further bare die 128) may include multiple conductive routing layers 140 formed in a layered manner to define a conductive routing layer stack 142. In the illustrated example, the conductive routing layer stack 142 includes conductive routing layers 140a-140h. It should be understood that the conductive routing region 104 may include any other number of conductive routing layers 140.

In some examples, the conductive routing region 104 comprises a redistribution layer (RDL) region, wherein the multiple conductive routing layers 140 comprise respective multiple RDL layers. Further, in some examples the multiple conductive routing layers 140 (e.g., RDL layers) comprise a number of metal layers and via layers formed in an alternating manner. For example, the example conductive routing layers 140a-140h (e.g., RDL layers) shown in FIG. 1 may include metal layers 140b, 140d, 140f, and 140h and via layers 140a, 140c, 140e, and 140g formed in an alternating manner. In some examples, respective metal layers may be formed concurrently with respective via layers, e.g., using a dual damascene process in which a metal layer with underlying vias are formed concurrently by a metal deposition. In other examples, metal layers and via layers may be formed separately, e.g., wherein respective metal layers and via layers are formed using a single damascene process or a process involving metal layer deposition and selective metal etch.

The conductive routing structure 110 formed in the conductive routing region 104 includes respective conductive elements 144 formed in one or more respective conductive routing layers 140. Conductive elements 144 may include, for example, metal lines or other metal elements formed in one or more metal layers 140b, 140d, 140f, and 140h, and vias or other or other metal elements formed in one or more via layers 140a, 140c, 140e, and 140g. In some examples, metal layers 140b, 140d, 140f, and 140h may comprise thick metal layers (e.g., thick copper layers) having a respective thickness greater than 20 μm.

Conductive elements 144 formed in respective conductive routing layers 140 may be formed in, and at least partially covered by, a dielectric region 148 comprising one or more dielectric materials. In some examples, the dielectric region 148 may comprise at least one low-k polymer dielectric, e.g., at least one epoxy, polyimide, and/or other dielectric material(s) having a respective dielectric constant less than 4.0.

Conductive elements 144 in the top metal layer 140h may define respective external contact elements 146 contactable by respective external devices (external to the IC package 100), e.g., to provide electrical connection to bare die 108 (in particular, to IC circuitry 114 in bare die 108) and/or further bare die 128 (in particular, to IC circuitry 130 in further bare die 128). In some examples, the external contact elements 146 in the top metal layer 140h may be referred to as bond pads.

Respective conductive elements 144 in multiple conductive routing layers 140a-140h may connect to each other to define various conductive paths in the conductive routing region 104, e.g., to route electrical signals to, or from, bare die 108 and/or further bare die 128. For example, respective conductive elements 144 may define a conductive path between bare die 108 and further bare die 128 allowing communication between bare die 108 and further bare die 128. In addition or alternatively, respective conductive elements 144 may define a conductive path between bare die 108 and a respective external contact element 146, e.g., wherein the respective conductive elements 144 are connected between the IC contact 118 (which is connected to IC circuitry 114) and a respective external contact element 146, allowing communication between bare die 108 and a respective external device connected to the respective external contact element 146. In addition or alternatively, respective conductive elements 144 may define a conductive path between the further bare die 128 and a respective external contact element 146, e.g., wherein the respective conductive elements 144 are connected between the IC contact 134 (which is connected to IC circuitry 130) to a respective external contact element 146, allowing communication between the further bare die 128 and a respective external device connected to the respective external contact element 146. The example conductive routing structure 110 shown in FIG. 1 is merely intended to illustrate several example conductive paths, and is thus illustrated using dashed lines. It should be understood that conductive routing structure 110 may include respective conductive elements 144 in any respective conductive routing layers 140 to define conductive path(s) between any respective devices.

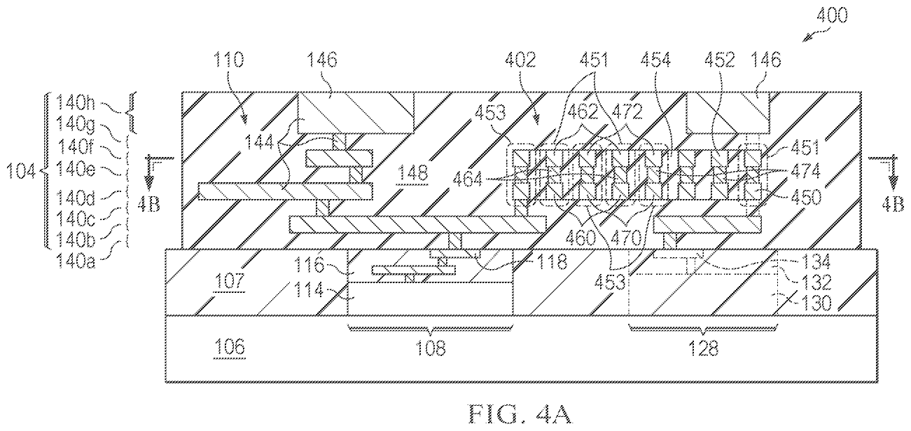

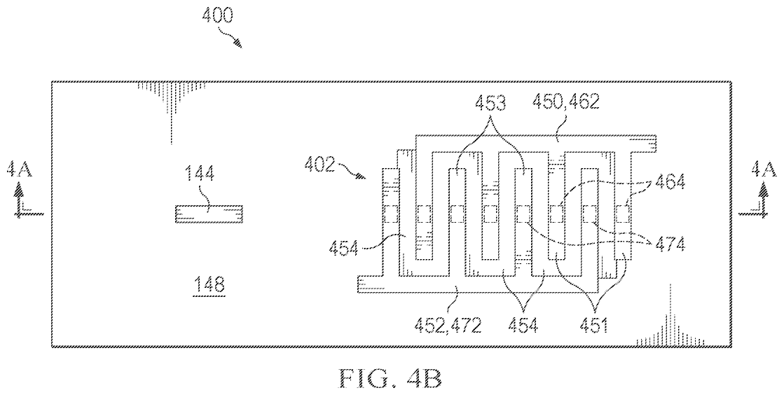

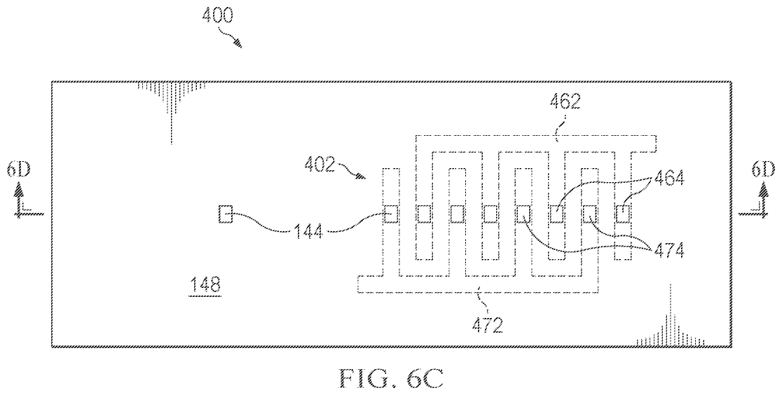

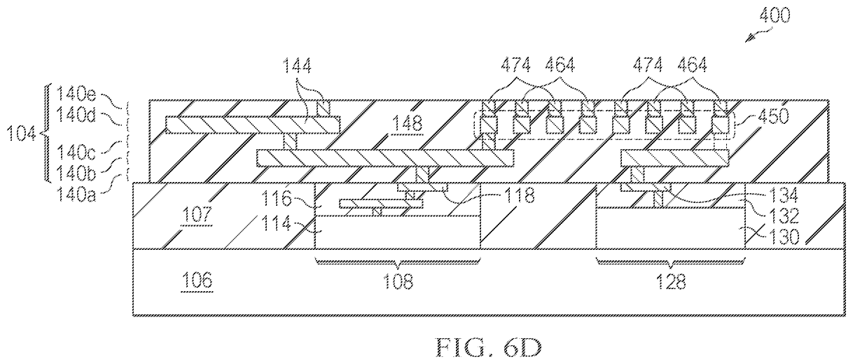

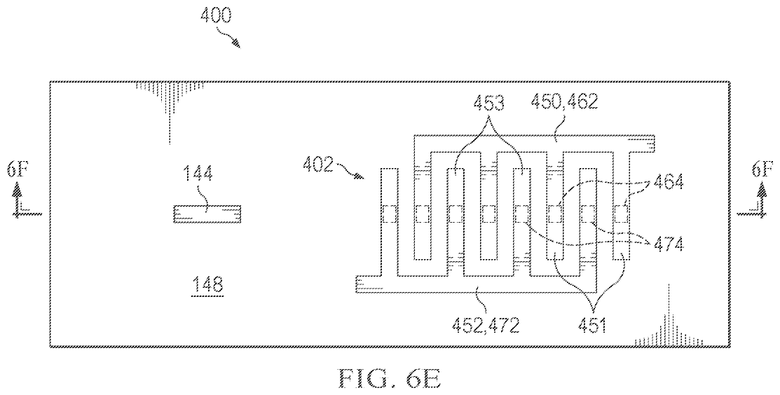

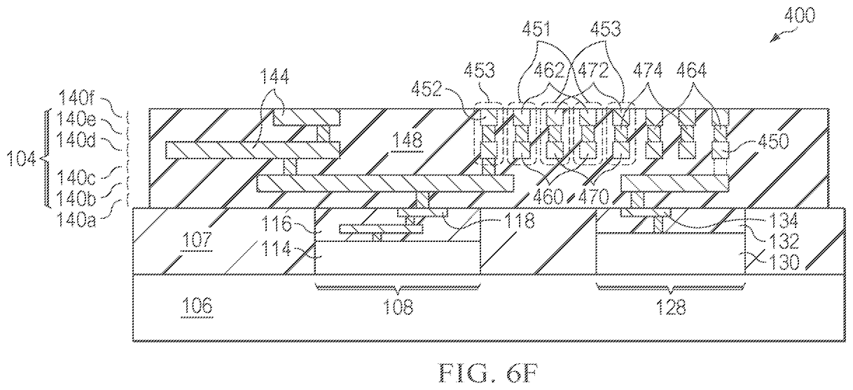

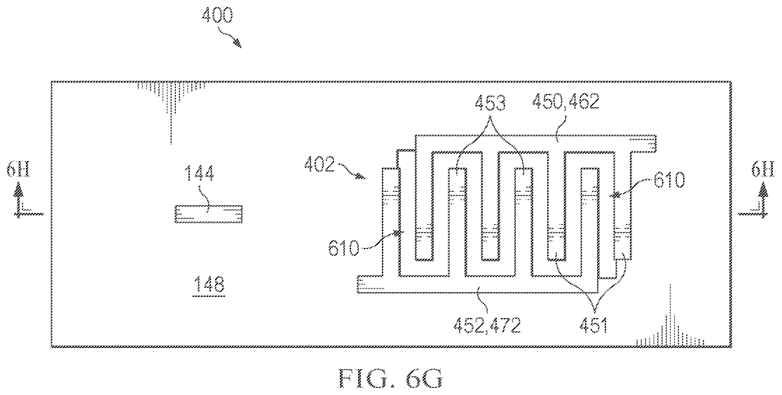

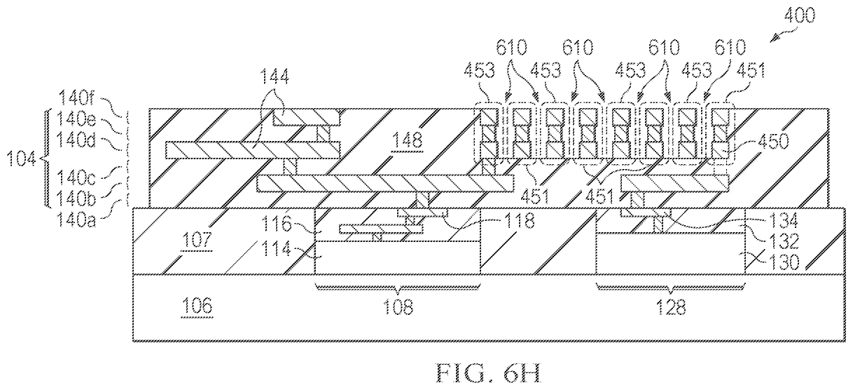

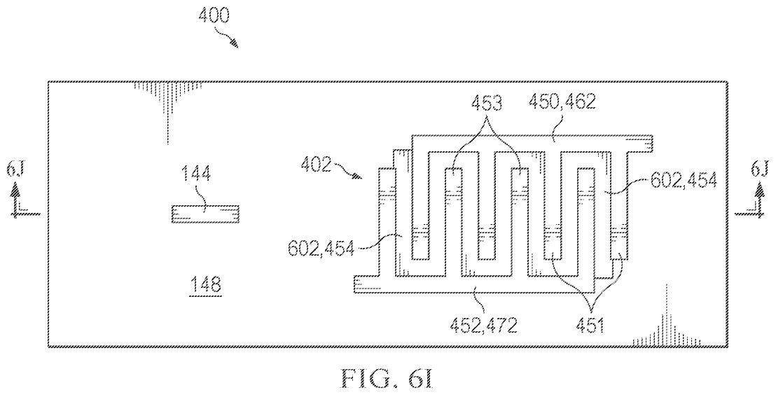

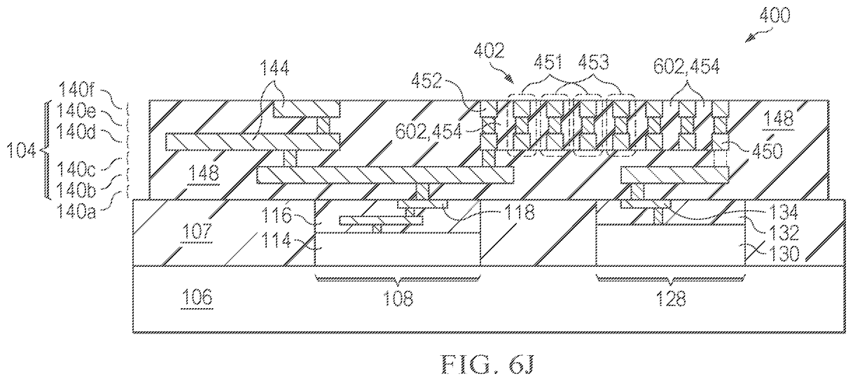

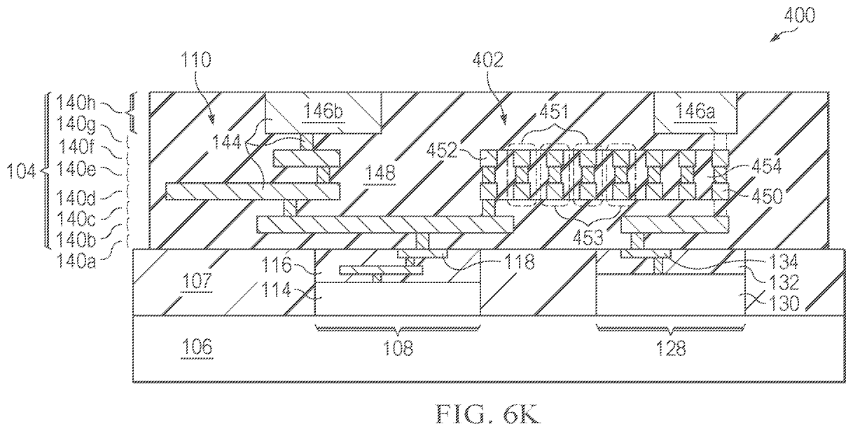

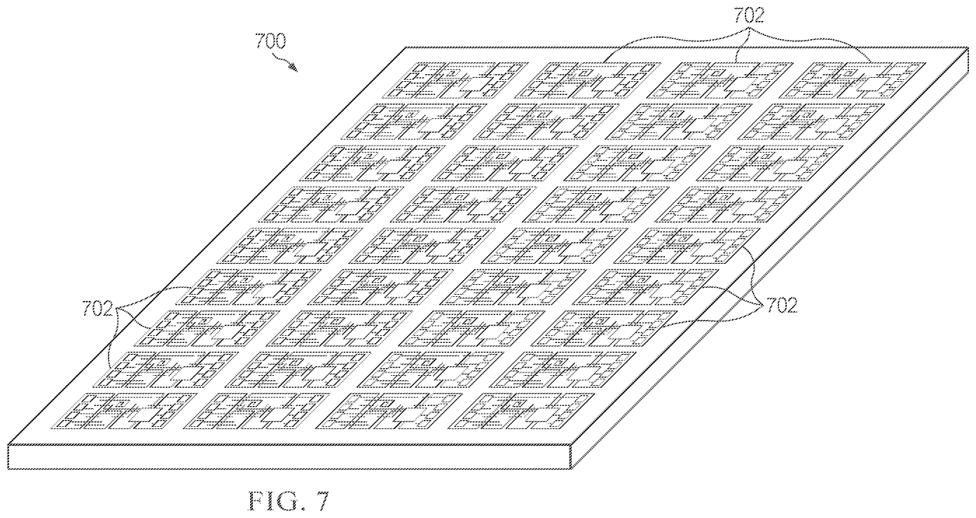

The in-package capacitor 102 formed in the conductive routing region 104 may include a first capacitor electrode 150 and a second capacitor electrode 152 formed in one or more conductive routing layers 140, and a capacitor dielectric element 154 formed between the first capacitor electrode 150 and second capacitor electrode 152. In the example shown in FIG. 1, the in-package capacitor 102 may comprise a vertically oriented capacitor, e.g., a vertically oriented Metal-Insulator-Metal (MIM) capacitor, wherein the first capacitor electrode 150 defines a first plate electrode, and the second capacitor electrode 152 defines a second plate electrode formed above the first plate electrode (first capacitor electrode 150) in the orientation of the IC package 100 shown in FIG. 1, i.e., where the first capacitor electrode 150 and the second capacitor electrode 152 are effectively parallel with substrate 106. In other examples, e.g., as shown in FIGS. 4A-4B (and FIGS. 6A-6K discussed below), a laterally oriented capacitor, e.g., Metal-Oxide-Metal (MOM) capacitor including interdigitated fingers arranged laterally relative to each other, may be formed in the conductive routing region 104.

In the example shown in FIG. 1, the first capacitor electrode 150 comprises a respective conductive element 144 formed in conductive routing layer 140d (e.g., metal layer 140d), the second capacitor electrode 152 comprises a second conductive element 144 formed in conductive routing layer 140f (e.g., metal layer 140f), and the capacitor dielectric element 154 is formed in conductive routing layer 140e (e.g., via layer 140e) between the conductive routing layers 140d and 140f. In some examples, the first capacitor electrode 150 and second capacitor electrode 152 may be formed from copper, aluminum, or any other suitable metal, and the capacitor dielectric element 154 may be formed from a high-k dielectric material having a dielectric constant above 4.0, for example aluminum oxide (Al₂O₃), hafnium oxide (HfO₂), or zirconium oxide (ZrO₂).

As shown in FIG. 1, the conductive routing structure 110 may include at least one conductive element 144 separate from the in-package capacitor 102 and formed in the same conductive routing layer 140d as the first capacitor electrode 150, at least one conductive element 144 separate from the in-package capacitor 102 and formed in the same conductive routing layer 140f as the second capacitor electrode 152, and/or at least one conductive element 144 (e.g., metal via) separate from the in-package capacitor 102 and formed in the same conductive routing layer 140e as the capacitor dielectric element 154.

In some examples, the in-package capacitor 102 may be electrically coupled along any of the example conductive paths discussed above. For example, the in-package capacitor 102 may be electrically coupled along a conductive path between the bare die 108 and the further bare die 128, to provide a galvanic isolation between the bare die 108 and the further bare die 128. As another example, the in-package capacitor 102 may be electrically coupled along a conductive path between the bare die 108 and a respective external contact element 146, to provide a galvanic isolation between the bare die 108 and an external device connected to the respective external contact element 146. As another example, the in-package capacitor 102 may be electrically coupled between two IC contacts of the bare die 108, e.g., to provide a galvanic isolation between discrete electronics within the bare die 108.

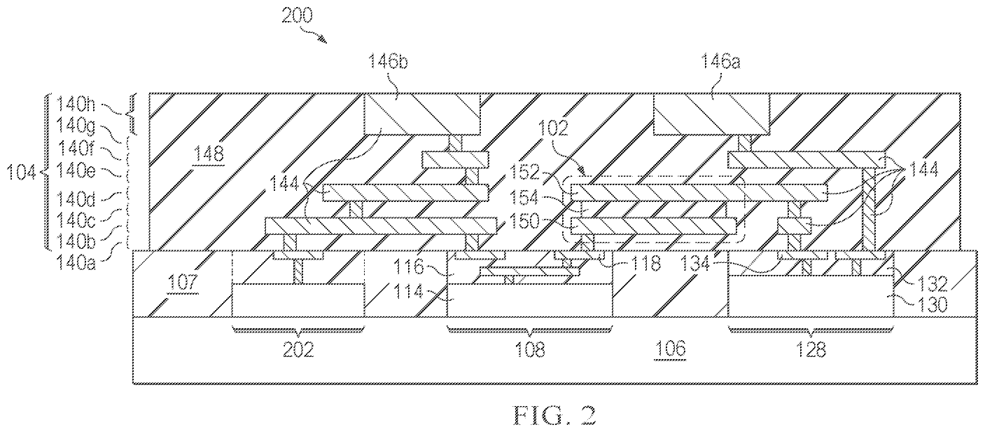

FIG. 2 is a cross-sectional side view of an example IC package 200 including the in-package capacitor 102 described above formed in the conductive routing region 104, according to one example. The example IC package 200 is generally similar to example IC package 100 with similar components having similar reference numbers. The example IC package 200 includes at least three bare dies, in particular the bare die 108, the further bare die 128, and a third bare die 202. The bare dies 108, 128, and 202 may respectively comprise any type or types of bare dies, e.g., any of the example types of bare dies listed above with respect to bare die 108. In some examples, the IC package 200 may comprise a chip-first package (e.g., a panel-level package (PLP) or a system-in-package (SiP)), wherein the bare dies 108, 128, and 202 are mounted to substrate 106 prior to forming the conductive routing region 104 (e.g., RDL region) over the bare dies 108, 128, and 202.

In the example IC package 200, the in-package capacitor 102 is conductively coupled between bare die 108 and further bare die 128, e.g., to provide a galvanic isolation between bare die 108 and bare die 128. Accordingly, in some examples the IC package 200 may comprise a “mixed voltage” device, i.e., wherein the bare die 108 and the further bare die 128 operate at substantially different voltages (e.g., wherein the bare die 108 is a high-voltage device and the further bare die 128 is a low-voltage device, or vice versa), and the in-package capacitor 102 provide a galvanic isolation between the bare dies 108 and 128. Further, as shown in FIG. 2, the conductive routing structure 110 connects the further bare die 128 to a respective external contact element 146a, and connects the bare die 108 directly to the bare die 202, and connects the bare dies 108 and 202 to a respective external contact element 146b.

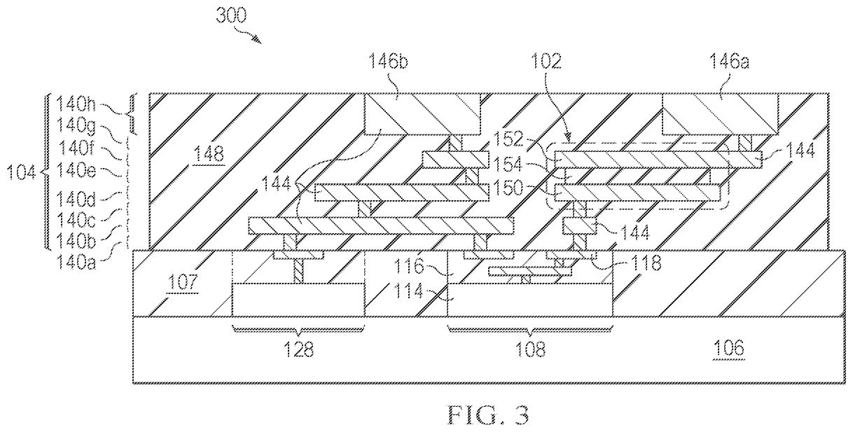

FIG. 3 is a cross-sectional side view of an example IC package 300 including the in-package capacitor 102 described above formed in the conductive routing region 104, according to one example. The example IC package 300 is generally similar to example IC package 100 with similar components having similar reference numbers. The example IC package 300 includes at least the bare die 108 and the further bare die 128. In some examples, the IC package 300 may comprise a may comprise a chip-first package (e.g., a panel-level package (PLP) or a system-in-package (SiP)), wherein the bare dies 108 and 128 are mounted to substrate 106 prior to forming the conductive routing region 104 (e.g., RDL region) over the bare dies 108 and 128.

In this example, the in-package capacitor 102 is conductively coupled between bare die 108 and a respective external contact element 146a, e.g., to provide a galvanic isolation between bare die 108 and an external device connected to the external contact element 146a. Further, as shown in FIG. 3, the conductive routing structure 110 connects the bare die 108 directly to the bare die 128, and connects the bare dies 108 and 128 to a respective external contact element 146b.

FIGS. 4A and 4B illustrate an example IC package 400 (e.g., a PLP, SiP, or other chip-first package) including an example in-package capacitor 402 formed in a conductive routing region 104, according to one example. FIG. 4A is a cross-sectional side view through line 4A-4A shown in FIG. 4B, and FIG. 4B is a cross-sectional top-down view through line 4B-4B shown in FIG. 4A.

The example IC package 400 is generally similar to example IC package 100 with similar components having similar reference numbers, but wherein (unlike the vertically oriented in-package capacitor 102), the example in-package capacitor 402 comprises a laterally oriented Metal-Oxide-Metal (MOM) capacitor including interdigitated fingers arranged laterally relative to each other. The example in-package capacitor 402 includes (a) a first comb shaped electrode 450 including multiple first elongated fingers 451, (b) a second comb shaped electrode 452 including multiple second elongated fingers 453 arranged in an interdigitated manner with the multiple first elongated fingers 451 of the first comb shaped electrode 450, and (c) a capacitor dielectric 454 between the multiple first elongated fingers 451 and the multiple second elongated fingers 453 to define a capacitive coupling between the first comb shaped electrode 450 and second comb shaped electrode 452.

The first comb shaped electrode 450 and the second comb shaped electrode 452 include respective conductive elements 144 formed in at least one common (same) conductive routing layer 140. For example, in the illustrated example, the first comb shaped electrode 450 and the second comb shaped electrode 452 include respective conductive elements 144 formed in conductive routing layers 140d, 140e, and 140f. In particular, the first comb shaped electrode 450 includes (a) a first comb-shaped structure 460 formed in conductive routing layer 140d (e.g., metal layer 140d), (b) a second comb-shaped structure 462 formed in conductive routing layer 140f (e.g., metal layer 140f), and (c) connecting elements 464 (e.g., vias) formed in conductive routing layer 140e (e.g., via layer 140e) conductively connecting the first comb-shaped structure 460 with the second comb-shaped structure 462. Similarly, the second comb shaped electrode 452 includes (a) a first comb-shaped structure 470 formed in conductive routing layer 140d (e.g., metal layer 140d), (b) a second comb-shaped structure 472 formed in conductive routing layer 140f (e.g., metal layer 140f), and (c) connecting elements 474 (e.g., vias) formed in conductive routing layer 140e (e.g., via layer 140e) conductively connecting the first comb-shaped structure 470 with the second comb-shaped structure 472.

Like the example in-package capacitor 102 shown in FIG. 1 and discussed above, the example in-package capacitor 402 shown in FIGS. 4A-4B may be electrically coupled to or along a conductive path defined by the conductive routing structure 110. For example, the in-package capacitor 402 may be electrically coupled along a conductive path between the bare die 108 and the (optional) further bare die 128, to provide a galvanic isolation between the bare die 108 and the further bare die 128. As another example, the in-package capacitor 402 may be electrically coupled along a conductive path between the bare die 108 and a respective external contact element 146, to provide a galvanic isolation between the bare die 108 and an external device connected to the respective external contact element 146. As another example, the in-package capacitor 402 may be electrically coupled between two IC contacts of the bare die 108, e.g., to provide a galvanic isolation between discrete electronics within the bare die 108.

It should be understood that the example in-package capacitors 102 and 402 shown in FIGS. 1-4B represent only two example structures for an in-package capacitor according to present disclosure. In other examples in-package capacitor with any other suitable shape may be formed in the conductive routing region formed over one or more bare dies. For example, an in-package capacitor may be formed with a cup-shaped outer electrode, a cup-shaped capacitor dielectric formed in an opening defined by the cup-shaped outer electrode, and an inner electrode formed in an opening defined by cup-shaped capacitor dielectric, for example as described in U.S. patent application Ser. No. 17/155,431 (issued as U.S. patent Ser. No. 11/545,544) or U.S. patent application Ser. No. 17/379,376 (published as U.S. Patent Application Publication No. 2022/0336577), the entire contents of which applications are hereby incorporated by reference.

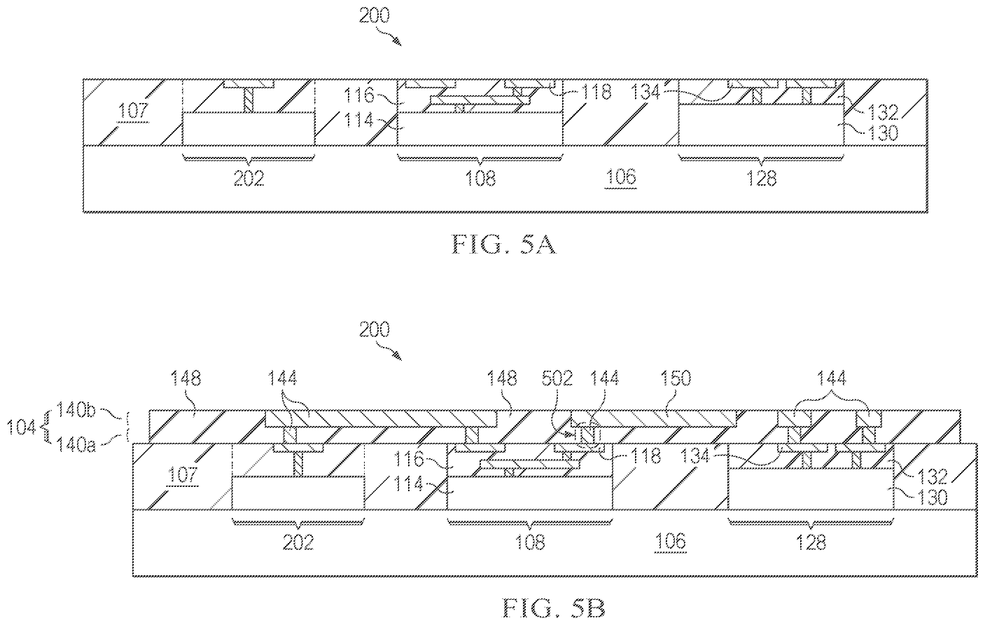

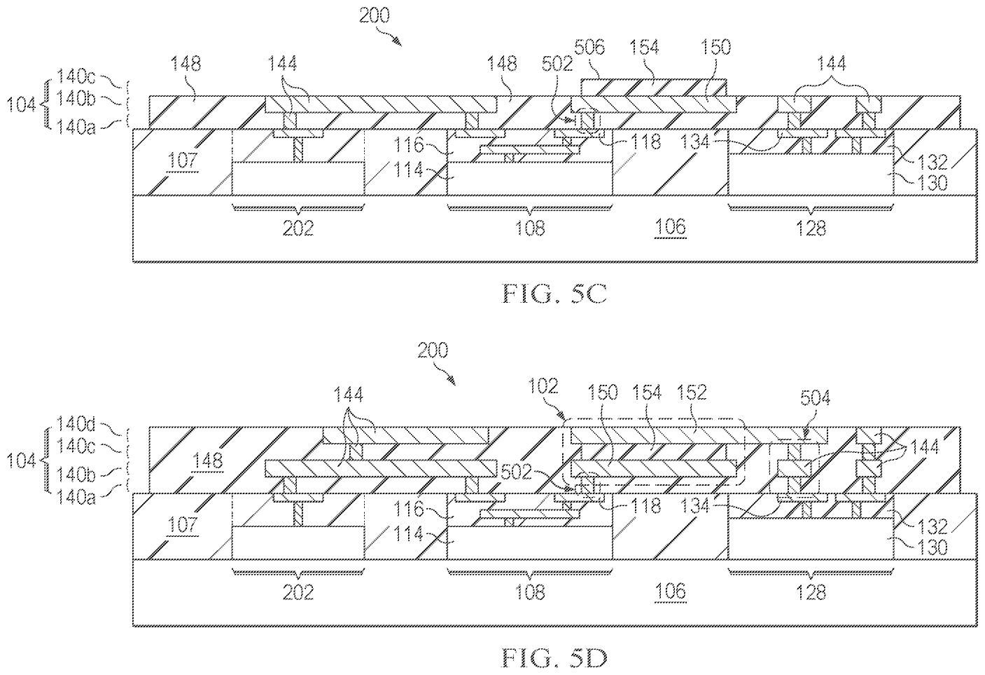

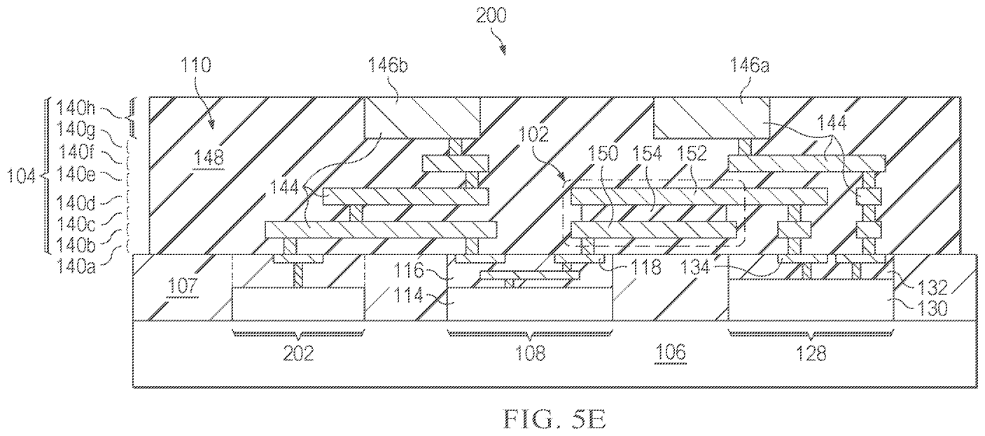

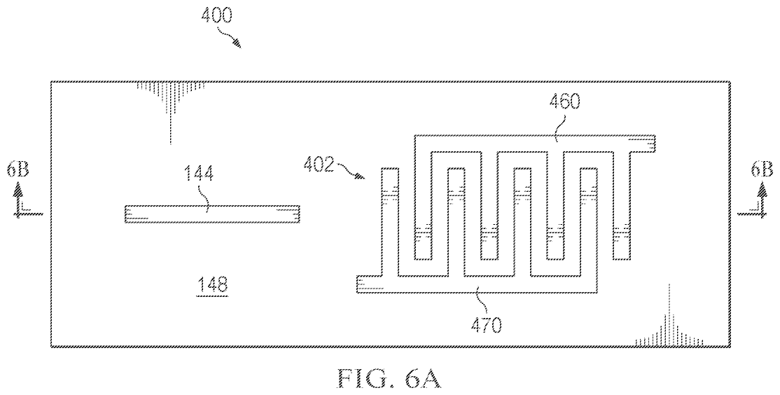

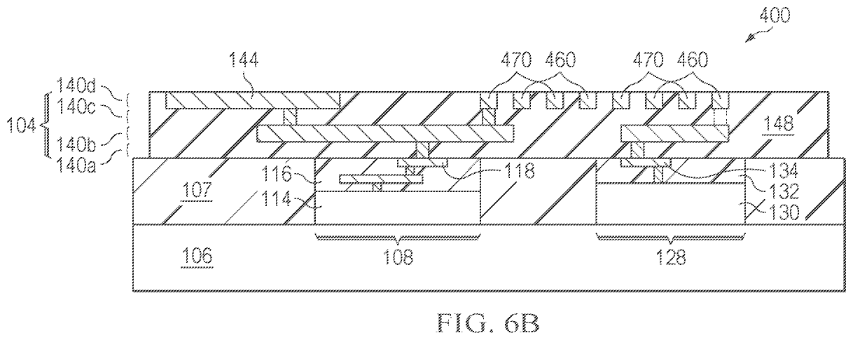

FIGS. 5A-5E are a series of cross-sectional side views showing an example chip-first method of forming the example IC package 200 shown in FIG. 2, e.g., including the conductive routing structure 110 and in-package capacitor 102 (e.g., MIM capacitor) formed in the conductive routing region 104 over example bare dies 108, 128, and 202. As shown in FIG. 5A, three bare dies 108, 128, and 202 may be mounted on the substrate 106, and mold compound 107 may be deposited over the bare dies 108, 128, and 202 and planarized to expose the upper surfaces of the bare dies 108, 128, and 202.

As shown in FIG. 5B, conductive routing layers 140a and 140b including respective conductive elements 144 may be formed, e.g., using any suitable process for forming RDL or other interconnect layers. For example, conductive routing layers 140a and 140b may be formed by distinct processes (e.g., wherein conductive routing layers 140a and 140b are respectively formed using a single damascene process or a process involving metal layer deposition and selective metal etch), or may be formed together, e.g., using a dual damascene process in which conductive elements 144 (e.g., metal lines) of conductive routing layer 140b are formed concurrently with underlying conductive elements 144 (e.g., vias) of conductive routing layer 140a.

As discussed above regarding FIG. 1, the conductive routing structure 110 and in-package capacitor 102 may be formed in (e.g., at least partially encapsulated by) a dielectric region 148 comprising one or more dielectric material, e.g., one or more low-k polymer dielectric, e.g., one or more epoxy, polyimide, and/or other low-k dielectric having a dielectric constant less than 4.0. Accordingly, forming conductive routing layers 140a-140h of the conductive routing region 104 may include forming respective conductive elements 144 in respective dielectric material(s), e.g., using any suitable process for forming RDL or interconnect structures including conductive elements formed in (e.g., at least partially encapsulated by) dielectric material. In some examples, the dielectric region 148 includes a common (same) dielectric material deposited or otherwise formed in the conductive routing layers 140a-140h. In other examples, the dielectric region 148 includes different dielectric materials deposited or otherwise formed in different conductive routing layers 140a-140h.

In this example, a respective conductive element 144 formed in conductive routing layer 140b defines the first capacitor electrode 150 of the in-package capacitor 102 being formed. The first capacitor electrode 150 is conductively connected to the bare die 108 by a routing structure 502 including conductive element(s) 144 of conductive routing layer 140a connected to the IC contact 118 of the bare die 108.

As shown in FIG. 5C, a high-k dielectric material 506 (e.g., having a dielectric constant above 4.0) may be deposited on the first capacitor electrode 150 using any suitable deposition process to define the dielectric element 154 of the in-package capacitor 102. Is some examples the high-k dielectric material 506 may comprise aluminum oxide (Al₂O₃), hafnium oxide (HfO₂), or zirconium oxide (ZrO₂), without limitation. In some examples, the high-k dielectric material 506 may be deposited using an additive manufacturing process, e.g., 3D printing, to form the dielectric element 154.

As shown in FIG. 5D, conductive routing layers 140c and 140d including respective conductive elements 144 may be formed, e.g., using any suitable process for forming RDL or other interconnect layers. For example, conductive routing layers 140c and 140d may be respectively formed by a distinct process (e.g., a single damascene process or by metal layer deposition and selective metal etch), or may be formed together (e.g., using a dual damascene process in which conductive elements 144 (e.g., metal lings) of conductive routing layer 140d are formed concurrently with underlying conductive elements 144 (e.g., vias) of conductive routing layer 140d. Conductive routing layer 140c (e.g., metal layer) may be formed with the same vertical thickness as the dielectric element 154, for example a vertical thickness in the range of 0-50 μm. For example, conductive routing layer 140c including respective conductive elements 144 formed therein, along with the dielectric element 154, may be collectively planarized.

In this example, a respective conductive element 144 formed in conductive routing layer 140d defines the second capacitor electrode 152 over the dielectric element 154. As shown in FIG. 5D, the second capacitor electrode 152 is conductively connected to the further bare die 128 by a routing structure 504 including conductive element(s) 144 connected to the IC contact 134 of the bare die 128. The first capacitor electrode 150, second capacitor electrode 152, and dielectric element 154 between the first capacitor electrode 150 and second capacitor electrode 152 define the in-package capacitor 102 as discussed above. Accordingly, in-package capacitor 102 is electrically coupled between the bare die 108 and bare die 128, to provide a galvanic isolation between the bare die 108 and bare die 128.

As shown in FIG. 5E, additional conductive routing layers 140 may be formed, in this example conductive routing layers 140e-140h, including additional conductive elements 144 of the conductive routing structure 110, in this example to connect the further bare die 128 to a respective external contact element 146a, and to connect the bare dies 108 and 202 to another respective external contact element 146b.

FIGS. 6A-6K are a series of cross-sectional side views showing an example chip-first method of forming the example IC package 400 shown in FIGS. 4A and 4B, e.g., including the conductive routing structure 110 and in-package capacitor 402 (e.g., MOM capacitor) formed in the conductive routing region 104 over example bare dies 108 and 128. As shown in FIG. 6A (top view) and FIG. 6B (cross-sectional side view through line 6B-6B shown in FIG. 6A), the bare dies 108 and 128 may be mounted on the substrate 106, and mold compound 107 may be deposited over the bare dies 108 and 128 and planarized.

As shown in FIG. 6A (top view) and FIG. 6B (cross-sectional side view through line 6B-6B shown in FIG. 6A), conductive routing layers 140a-140d including respective conductive elements 144 may be formed in dielectric region 148, e.g., using any suitable process for forming RDL or other interconnect layers.

In this example, a pair of conductive element 144 formed in conductive routing layer 140d define (a) the first comb-shaped structure 460 of the first comb shaped electrode 450 being formed and (b) the second comb-shaped structure 470 of the second comb shaped electrode 452 being formed. In this example, the second comb-shaped structure 470 is conductively connected to the bare die 108 (in particular to the IC contact 118) by respective conductive elements 144, and the first comb-shaped structure 460 may be optionally connected to the further bare die 128 (in particular to the IC contact 134) by respective conductive elements 144 (alternatively, the first comb-shaped structure 460 may be connected to an external contact element 146a, e.g., as shown in FIG. 6K discussed below).

As shown in FIG. 6C (top view) and FIG. 6D (cross-sectional side view through line 6D-6D shown in FIG. 6C), conductive routing layer 140e may be formed, including multiple conductive elements 144, including (a) connecting vias 464 (for connecting first comb-shaped structure 460 to the subsequently-formed second comb-shaped structure 462 of the first comb shaped electrode 450) and connecting vias 474 (for connecting first comb-shaped structure 470 to the subsequently-formed second comb-shaped structure 472 of the second comb shaped electrode 452, and (c) one or more further conductive elements 144 (e.g., one or more vias) separate from the MOM capacitor 402.

As shown in FIG. 6E (top view) and FIG. 6F (cross-sectional side view through line 6F-6F shown in FIG. 6E), conductive routing layer 140f may be formed, including (a) the second comb-shaped structure 462 (connected to the first comb-shaped structure 460 of the first comb shaped electrode 450 by connective vias 464), (b) the second comb-shaped structure 472 (connected to the first comb-shaped structure 470 of the first comb shaped electrode 452 by connective vias 474), and (c) one or more further conductive elements 144 separate from the MOM capacitor 402.

As shown in FIG. 6F, the first comb-shaped structure 460, second comb-shaped structure 462, and connecting vias 464 collective define the first comb shaped electrode 450, including elongated fingers 451 (see FIG. 6E); and the first comb-shaped structure 470, second comb-shaped structure 472, and connecting vias 474 collective define the second comb shaped electrode 452, including elongated fingers 453 (see FIG. 6E) arranged interdigitated with the elongated fingers 451 of the first comb shaped electrode 450.

As shown in FIG. 6G (top view) and FIG. 6H (cross-sectional side view through line 6H-6H shown in FIG. 6G), opening(s) 610 may be formed in the dielectric region 148, e.g., between adjacent elongated fingers 451 and 453 of the first and second comb shaped electrodes 450 and 452, respectively, e.g., using a laser-based drilling process or other material removal process.

As shown in FIG. 6I (top view) and FIG. 6J (cross-sectional side view through line 6J-6J shown in FIG. 6I), a high-k dielectric material 602 (e.g., aluminum oxide (Al₂O₃), hafnium oxide (HfO₂), or zirconium oxide (ZrO₂), or other material having a dielectric constant above 4.0) may be deposited in the opening(s) 610 between elongated fingers 451 and 453 to define the capacitor dielectric 454 between respective adjacent elongated fingers 451 and 453.

As shown in FIG. 6K, additional conductive routing layers 140 may be formed, in this example conductive routing layers 140g-140h, including additional conductive elements 144 of the conductive routing structure 110, in this example to connect the bare die 108 to the respective external contact element 146b, and optionally to connect the first comb shaped electrode 450 to the respective external contact element 146a, to provide a capacitive coupling between the bare die 108 and an external device connected to the external contact element 146b. Alternatively, as discussed above, the first comb shaped electrode 150 may be connected to the further bare die 128 (e.g., and not connected to an external contact element) to provide a capacitive coupling between the bare dies 108 and 128.

As discussed above, in some examples an IC package including at least one in-package capacitor may be formed as a panel-level package (PLP). FIG. 7 is a three-dimensional view from above of a panel 700 including an array of panel-level packages (PLPs) 702 formed thereon, wherein respective PLPs 702 include at least one in-package capacitor according to the present disclosure. For example, respective PLPs 702 may correspond with or be similar to any of the example IC packages 100, 200, 300, or 400 shown in the drawings and described above. After forming the array of PLPs on the panel 700, individual PLPs 702 may be separated (singulated) by cutting the panel 700 at respective locations. In one example, the panel 700 may comprise a 24 inch by 24 inch panel substrate formed from a plastic material.

1. An integrated circuit (IC) package, comprising:
a substrate;
a bare die mounted on the substrate, the bare die including IC circuitry, a dielectric region at least partially encapsulating the IC circuitry, and an IC contact exposed through the dielectric region;
a conductive routing region including multiple conductive routing layers formed over the bare die;
a conductive routing structure formed in the multiple conductive routing layers, wherein the conductive routing structure is conductively connected to the IC contact of the bare die; and
a capacitor formed in the conductive routing region, the capacitor including:
a first capacitor electrode and a second capacitor electrode formed in one or more conductive routing layers of the multiple conductive routing layers; and
a capacitor dielectric element formed between the first capacitor electrode and the second capacitor electrode.

2. The IC package of claim 1, wherein the IC package comprises a chip-first package.

3. The IC package of claim 1, wherein the conductive routing region comprises a redistribution layer (RDL) region, wherein respective conductive routing layers of the multiple conductive routing layers comprise respective RDL layers.

4. The IC package of claim 1, wherein the conductive routing structure includes at least one conductive element separate from the capacitor and formed in a common conductive routing layer as the first capacitor electrode or the second capacitor electrode.

5. The IC package of claim 1, wherein the first capacitor electrode and the second capacitor electrode are formed in different conductive routing layers of the multiple conductive routing layers.

6. The IC package of claim 1, wherein the first capacitor electrode and the second capacitor electrode are at least partially formed in a common conductive routing layer of the multiple conductive routing layers.

7. The IC package of claim 1, wherein the capacitor dielectric element is formed in a via layer between the first plate electrode and second plate electrode.

8. The IC package of claim 1, wherein:
the first capacitor electrode comprises a first comb-shaped structure formed in a first conductive routing layer of the multiple conductive routing layers, the first comb-shaped structure including first elongated fingers; and
the second capacitor electrode comprises a second comb-shaped structure formed in the first conductive routing layer, the second comb-shaped structure including second elongated fingers interdigitated with the first elongated fingers of the first comb-shaped structure.

9. The IC package of claim 1, wherein:
the multiple conductive routing layers include multiple metal layers alternating with multiple via layers;
the first capacitor electrode is formed at least in part in a first respective metal layer of the multiple metal layers;
the second capacitor electrode is formed at least in part in a second respective metal layer of the multiple metal layers; and
the capacitor dielectric element is formed in a respective via layer of the multiple via layers.

10. The IC package of claim 1, wherein:
the IC package includes a further bare die mounted to the substrate; and
the capacitor is electrically coupled between the bare die and further bare die.

11. The IC package of claim 1, wherein:
the conductive routing structure includes an external contact element contactable by an external device; and
the capacitor is electrically coupled between the bare die and the external contact element.

12. A method of forming an integrated circuit (IC) package, comprising:
mounting a bare die on a substrate, the bare die including IC circuitry, a dielectric region at least partially encapsulating the IC circuitry, and an IC contact exposed through the dielectric region; and
after mounting the bare die on the substrate, forming a conductive routing region including multiple conductive routing layers over the bare die;
wherein forming the conductive routing region includes:
forming a conductive routing structure including conductive elements formed in respective conductive routing layers of the multiple conductive routing layers, wherein the conductive routing structure is conductively connected to the IC contact of the bare die; and
forming a capacitor including:
forming a first capacitor electrode and a second capacitor electrode in one or more conductive routing layers of the multiple conductive routing layers; and
forming a capacitor dielectric element between the first capacitor electrode and the second capacitor electrode.

13. The method of claim 12, wherein forming the conductive routing region including multiple conductive routing layers comprises forming a redistribution layer (RDL) region including multiple RDL layers.

14. The method of claim 12, comprising forming at least one conductive element of the conductive routing structure, separate from the capacitor, in a common conductive routing layer as the first capacitor electrode or the second capacitor electrode.

15. The method of claim 12, wherein:
the multiple conductive routing layers include multiple metal layers alternating with multiple via layers;
the first capacitor conductive element is formed in a first respective metal layer of the multiple metal layers;
the second capacitor conductive element is formed in a second respective metal layer of the multiple metal layers; and
the capacitor dielectric element is formed in a respective via layer of the multiple via layers between the first respective metal layer of the multiple metal layers and the second respective metal layer of the multiple metal layers.

16. The method of claim 12, wherein forming the capacitor dielectric element comprising:
using a laser-based removal process to form at least one opening adjacent the first capacitor electrode; and
filling the at least one opening with a dielectric material.

17. An integrated circuit (IC) package, comprising:
a substrate;
a first bare die and a second bare die mounted on the substrate; and
a conductive routing layer stack formed over the first bare die and second bare die, the conductive routing layer stack including:
at least one conductive routing structure conductively connected to at least one of the first bare die and the second bare die; and
a capacitor including:
a first capacitor electrode conductively connected to the first bare die;
a second capacitor electrode conductively connected to the second bare die; and
a capacitor dielectric element formed between the first capacitor electrode and the second capacitor electrode.

18. The IC package of claim 17, wherein the IC package comprises a chip-first package.

19. The IC package of claim 17, wherein the conductive routing layer stack comprises multiple redistribution layer (RDL) layers.

20. The IC package of claim 17, wherein the capacitor comprises a Metal-Insulator-Metal (MIM) capacitor.

21. The IC package of claim 17, wherein the capacitor comprises a Metal-Oxide-Metal (MOM) capacitor.
